(19) United States
(12) Patent Application Publication
(10) Pub. No.: US 2025/0176342 A1
(43) Pub. Date: May 29, 2025

(54) SEMICONDUCTOR DEVICE AND METHOD FOR TRANSFERRING A SEMICONDUCTOR DEVICE

(71) Applicant: ams-OSRAM International GmbH, Regensburg (JP)

(72) Inventors: Sebastian Wittmann, Regenstauf (DE); Tobias Berthold, Wenzenbach (DE); Thomas Schwarz, Regensburg (DE); Markus Boss, Regensburg (DE)

(21) Appl. No.: 18/834,182

(22) PCT Filed: Feb. 1, 2023
(86) PCT No.: PCT/EP2023/052446

§ 371 Date: Jul. 29, 2024

(30) Foreign Application Priority Data
Feb. 1, 2022 (DE) 10 2022 102 366.4

(51) Int. Cl. H10H 29/02; H10H 20/82; H10H 20/841

(52) U.S. Cl. CPC H10H 29/02; H10H 20/82; H10H 20/841

(57) ABSTRACT

In an embodiment a semiconductor device includes a semiconductor body configured to generate light of a first main wavelength, wherein the semiconductor body has a first main side having at least one contact region and a second main side opposite the first main side having a light-emitting surface and a coating arranged on the second main side, wherein the coating is substantially transparent to light in a wavelength range of the first main wavelength and is absorbent or reflective to light in a wavelength range of a second main wavelength, wherein the wavelength range of the second main wavelength is below the wavelength range of the first main wavelength and below 450 nm, and wherein the coating includes a multilayer coating sequence of materials of different refractive indices.

### CROSS-REFERENCE TO RELATED APPLICATIONS

This patent application is a national phase filing under section 371 of PCT/EP2023/052446, filed Feb. 1, 2023, which claims the priority of German patent application 10 2022 102 366.4, filed Feb. 1, 2022, each of which is incorporated herein by reference in its entirety.

### TECHNICAL FIELD

The present invention relates to a semiconductor device and a method for transferring a semiconductor device.

### BACKGROUND

Semiconductor components, including so-called μLEDs, must be transferred from a carrier or source substrate to a target substrate. The term “target substrate” can be understood to mean another temporary carrier, but also a circuit board, a PCB, a backplane or similar. A method that can transfer a large number of components in a very short time is used for this purpose. Such a transfer is particularly difficult with small components, the above-mentioned μLEDs, as their lateral dimensions are only in the range of a few μm.

When components are transferred using a so-called laser lift-off process, components are detached from the carrier substrate by a laser pulse and then transferred to the target substrate. In a second step, the component is then attached to the target substrate. However, the irradiated laser energy can not only heat up the component, which can lead to problems, especially with temperature-sensitive elements, but the laser energy can also penetrate the semiconductor component up to the active layer and cause accelerated ageing or other effects that reduce efficiency.

### SUMMARY

In conventional processes, the difficulties mentioned above are primarily addressed by adapting the adhesive layers or the carrier substrate. Although this is certainly effective, other disadvantages may have to be accepted, such as a change in adhesive strength or uneven peeling.

The inventors now propose a semiconductor component comprising a semiconductor body designed to generate light of a first main wavelength. This comprises at least one, and in some embodiments also two, contact areas on a first main side. A light-emitting surface of the semiconductor component is arranged on a second main side opposite the first main side. On the second main side, the semiconductor device comprises a coating which is substantially transparent to light in a wavelength range of the first main wavelength. For light in a wavelength range of a second main wavelength, however, the coating is designed to be absorbent or reflective. Furthermore, the wavelength range of the second main wavelength is below the wavelength range of the first main wavelength. In other words, the second main wavelength is significantly more energetic than the first main wavelength. In some aspects, it is proposed that the wavelength range of the second main wavelength is in the range below 450 nm and in particular below 420 nm and in particular below 390 nm. In some other aspects, the wavelength range of the second main wavelength may also be between 520 nm and 450 nm.

The proposed semiconductor device thus creates a device in which, in contrast to conventional approaches, the coating required for the subsequent transfer process is not arranged on a glass substrate but on the semiconductor device itself. The coating is essentially transparent for the emission wavelength of the semiconductor component and, in particular, the semiconductor body. Absorption or reflection only takes place in a light wavelength range that is used for the transfer process of the semiconductor device to a PCB or another carrier. This reduces the thermal load on the semiconductor component during the transfer process, as the laser energy used to detach the component does not heat up the semiconductor component itself. Due to the high absorption or reflection, the irradiated laser energy also does not reach the active layer of the semiconductor component and thus does not lead to the accelerated ageing mentioned above.

In this context, as already indicated, the layer can be either absorbent or reflective. In the case of an absorbing layer on the second main side, the irradiated laser energy leads to heating at the interface between the coating and a possible adhesive layer on a carrier substrate. Penetration of the laser light into the semiconductor body and into the active zone is avoided or at least greatly reduced by the absorption. In some embodiments, such an absorbing coating is designed as an optical long-pass filter. The coating can thus comprise an absorption in the range of greater than 80% at the light wavelength for detachment and an absorption of less than 20% and in particular less than 10% at the emission wavelength of the semiconductor body.

A reflective coating on the second main side also prevents the laser light from penetrating the semiconductor body to cause detachment. Incident laser light is backscattered by the reflective coating and can thus be absorbed in an adhesion layer. This also increases the overall absorption probability for the adhesion layer, as an unabsorbed portion of the light reaches the adhesion layer again. In some embodiments, such a reflective coating comprises a reflectance of more than 80% in the range of the second wavelength and, in particular, more than 90% in the range of the second wavelength. However, the reflection in the range of the emission wavelength of the semiconductor body is only low and is below 20%, in particular below 10%.

A reflective coating of the proposed type can be produced, for example, by a dielectric mirror or a Bragg reflector that is optimized for the wavelength range of the second main wavelength. In another embodiment, it is possible to apply a thin coating of silicon nitride, SiN, as a coating. In some embodiments, this coating is only a few atomic layers down to one atomic layer thick.

In some embodiments of a dielectric mirror or a Bragg reflector, a large number of layers are provided which comprise different refractive indices. A suitable choice of refractive indices, thickness and number of layers can thus produce a reflectance in the range of the second main wavelength. In some embodiments, the thickness of the aforementioned coating is between 50 nm and 2500 nm.

In some embodiments of the semiconductor device, the coating on the light-emitting surface of the second main side is at least partially removed. On the one hand, this can be done during the manufacturing process by removing the coating from the light-emitting surface. Alternatively, however, it is also possible to dissolve a light-absorbing emission surface by absorbing the light during the transfer process, so that the coating is removed from the light-emitting surface after the transfer process has been completed.

Another aspect relates to the embodiment of the light emitting surface having a roughened or other regular or irregular surface texture. In some embodiments, the light-emitting surface comprises a regular surface structure. This structure can be designed in such a way that incident light of the second main wavelength is optimally reflected even at different angles of incidence. Such an optimization can hardly or not at all be achieved with random roughening, so that in some embodiments the roughening is periodic and in particular regular. It may be provided that the light-emitting surface comprises a cylindrical, cuboid or pyramid-shaped surface structure. In these embodiments, the coating extends along the roughening.

In some further embodiments, it is provided that side faces of the semiconductor body which, starting from the second main side, extend at an angle of less than 90° towards the first main side are also at least partially provided with the coating. In this respect, the coating thus also extends to side faces of the semiconductor body and not only to the second main side. In some embodiments, the coating is made with silicon nitride SiN or another inorganic material. For embodiments in which the coating is to have a particularly strong absorbing effect in the region of the second main wavelength, it may be intended to use an organic material which evaporates or otherwise dissolves due to the irradiated laser light and thus reduces the adhesion between the semiconductor body and an adhesive layer or the substrate.

Another aspect relates to a method for transferring a semiconductor device. The semiconductor device comprises a semiconductor body designed to generate light of a first main wavelength. It comprises a first main side with at least two contact areas and a second main side opposite the first main side with an emission surface. A coating is arranged on the second main side, which is essentially transparent for light in a wavelength range of the first main wavelength. For light in a wavelength range of a second main wavelength, the coating is absorbent or reflective. Furthermore, the wavelength range of the second main wavelength is below the wavelength range of the first main wavelength. In other words, the second main wavelength is thus smaller than the first main wavelength and is in particular below 450 nm, 420 nm or below 390 nm.

In an aspect, a carrier substrate is now provided on which an essentially transparent adhesive layer is applied. A plurality of semiconductor components with the second main side is arranged thereon. The second main side is thus attached to the transparent adhesive layer. A light pulse with the second main wavelength is then irradiated and the irradiated energy is absorbed by the coating of the semiconductor component. The irradiated energy is selected so that the absorption reduces the adhesive force between the coating and the adhesive layer in such a way that the semiconductor component detaches.

In another aspect according to the proposed principle, a carrier substrate is provided on which an adhesive layer absorbing the second main wavelength is arranged. A plurality of semiconductor components with the second main side are then attached to this substrate. A light pulse with the second main wavelength is then also irradiated and at least part of the irradiated light pulse is reflected by the coating. This reflection in turn leads to the adhesive layer, which can absorb the reflected part of the light again. The heating caused by the energy supplied reduces the adhesive force between the coating and the adhesive layer to such an extent that the semiconductor component detaches.

In both cases, the irradiated energy of the light pulse interacts with the coating to reduce the adhesion between the semiconductor device and a carrier substrate, causing it to detach from the carrier substrate. This can occur on the one hand by absorption in the coating on the semiconductor component, and on the other hand by reflection of the irradiated energy and absorption of the reflected energy in a layer.

The core idea of the proposed principle is thus to arrange the coating that causes the semiconductor device to detach from the carrier not on the carrier substrate, but on the semiconductor device. In other words, the semiconductor component is provided with this additional coating during production, which is transparent for the emission wavelength on the one hand, but reflective or absorbent for the wavelength of the detachment light. In both cases, this prevents penetration of the stripping light into the semiconductor body and into the active zone, so that damage or additional ageing effects are avoided or greatly reduced. In addition, more reproducible detachment behavior can be achieved, as the coating can be applied particularly accurately and precisely beyond the manufacturing process.

In one aspect, the adhesive layer arranged between the semiconductor device with its coating and the carrier substrate is structured and only covers part of the second main side. In this way, the adhesion provided can be reduced to a minimum, so that the laser energy applied can also be reduced with advantage. In this aspect, it is expedient in some embodiments to make the carrier substrate for the light of the second main wavelength essentially transparent. In this way, the light of the second main wavelength can be irradiated backwards, i.e. directly onto the second main side and the coating arranged thereon.

In one aspect of the proposed principle, a carrier substrate is provided which comprises a plurality of recesses. In a subsequent step, the recesses are filled with the material of the adhesive layer. As a result, although the semiconductor component lies flat on the carrier substrate, it is only held to the carrier substrate in a partial area, namely in an area above the recess, by the material of the adhesive layer. With suitable positioning and design, the light of the second main wavelength can be directed directly onto the material in the recess.

In an alternative embodiment, a carrier substrate is provided and an unstructured adhesive layer is applied to it. This adhesive layer is then structured in such a way that the adhesive layer comprises a plurality of separate areas. Each of these areas comprises an area that is either smaller than or substantially equal to an area of the second main side.

### BRIEF DESCRIPTION OF THE DRAWINGS

Further aspects and embodiments according to the proposed principle will become apparent with reference to the various embodiments and examples described in detail in connection with the accompanying drawings.

FIG. 1 shows a design of a semiconductor device according to the proposed principle, which realizes a long-pass filter with an exemplary associated absorption curve;

FIG. 2 shows an embodiment of such semiconductor devices according to the proposed principle, as they are prepared for a transfer process;

FIG. 3 shows a further embodiment of such semiconductor devices according to the proposed principle, as they are prepared for a transfer process;

FIGS. 4A to 4C show a schematic view of a manufacturing process for a method for transferring semiconductor devices according to the proposed principle;

FIG. 5 shows a further embodiment of a semiconductor device according to the proposed principle, which is realized with a dielectric layer with an exemplary associated reflection curve;

FIG. 6 shows a further embodiment of such semiconductor components according to the principle of FIG. 5, as they are prepared for a transfer process;

FIG. 7 is a first embodiment of a semiconductor device with a periodic structure;

FIG. 8 shows a second embodiment of a semiconductor device with a periodic structure;

FIG. 9 shows an embodiment of a semiconductor device with a coating that comprises the shape shown in the reflection curve;

FIG. 10 shows various embodiments of an adhesive layer suitable for reflective or absorbent coatings.

### DETAILED DESCRIPTION OF ILLUSTRATIVE EMBODIMENTS

The following embodiments and examples show various aspects and their combinations according to the proposed principle. The embodiments and examples are not always to scale. Likewise, various elements may be shown enlarged or reduced in size in order to emphasize individual aspects. It is understood that the individual aspects and features of the embodiments and examples shown in the figures can be readily combined with each other without affecting the principle of the invention. Some aspects have a regular structure or shape. It should be noted that slight deviations from the ideal shape may occur in practice without, however, contradicting the inventive concept.

In addition, the individual figures, features and aspects are not necessarily shown in the correct size, and the proportions between the individual elements are not necessarily correct. Some aspects and features are emphasized by enlarging them. However, terms such as “above”, “above”, “below”, “below”, “larger”, “smaller” and the like are shown correctly in relation to the elements in the figures. It is thus possible to deduce such relationships between the elements on the basis of the figures.

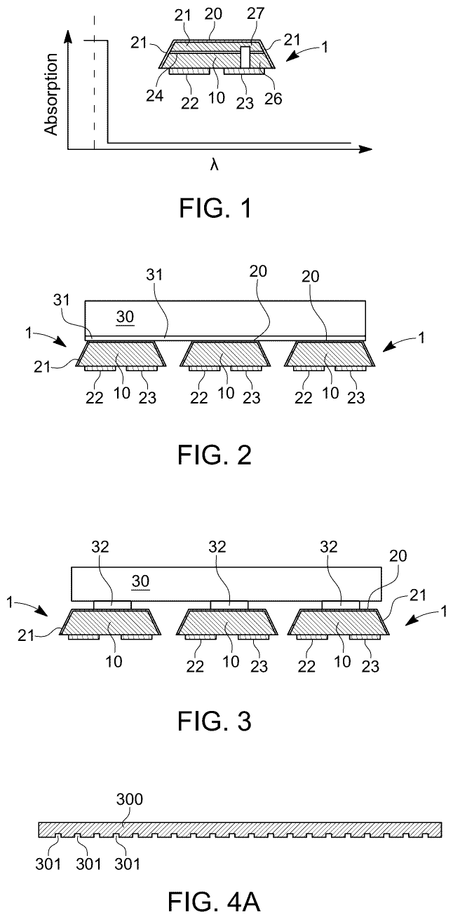

FIG. 1 shows a first example of a semiconductor device based on the proposed principle, in which the coating is particularly suitable for absorption at the second main wavelength. The semiconductor component 1 is designed as a horizontal optoelectronic component. The term horizontal optoelectronic component is understood to mean a component in which the contact pads are located on one side of the component and, in particular, on the side of the component opposite the emission surface.

In the embodiment example shown, the semiconductor device comprises a semiconductor body 10 with a first doped layer 26, a second doped layer 25 and an active zone 24 arranged in between. A first contact pad 22 on the underside of the semiconductor device makes contact with the doped layer 26, while a second contact pad 23 extends through the doped layer 26 and the active zone in an insulated manner and makes contact with the second doped layer 25. Configurations of these contacts and also the various connections in the differently doped regions 25 and 26 are familiar to the skilled person at this point. During manufacture, a large number of such semiconductor components are built up on a growth substrate and then separated from each other by means of a mesa structure. This mesa structure leads to the inclined side walls of the semiconductor device 1 shown in the embodiment examples.

According to an embodiment, an emission surface 27 is now arranged on the second main side. In the present embodiment example, the emission surface 27 thus also corresponds to the second main side, since light is emitted from the entire main side during operation of the component. A coating 20 is now applied to the surface of the second main side. Its material extends not only to the surface of the second main side, but also along the side faces of the semiconductor component and forms the coating 21 there.

The coating 20 on the second main side shows an absorption behavior that depends on the wavelength. The absorption behavior is shown schematically in the diagram also shown in FIG. 1. In general, the absorption in the visible range of the spectrum, i.e. in particular in the blue, green and red spectrum, is very low, i.e. the coating 20 is essentially transparent for the wavelength range of the visible spectrum. As a result, the light generated in the active zone 24 can be emitted through the coating 20 during operation of the semiconductor device 1.

On the other hand, the coating 20 shows very strong absorption in a range below 400 nm in the order of 80%-90% or even higher. The second main wavelength, which is used to detach the semiconductor device from a carrier substrate during a transfer process, is located in this wavelength range. FIGS. 2 and 3 show such an embodiment in which semiconductor devices are attached to a carrier substrate.

FIG. 2 shows three such semiconductor devices 1 with their semiconductor bodies 10, each of which comprises a contact pad 22 and 23 on its underside. The semiconductor components 1 are attached with their second main side and their coating 20 to an adhesive layer 31, which in turn is connected to a glass substrate 30.

To transfer the semiconductor devices 1, a light pulse of the second main wavelength, also referred to as a transfer laser pulse or simply as a laser pulse, is now irradiated through the transparent glass substrate 30 and the adhesive layer 31, which is transparent for this wavelength, onto the coating 20 of the semiconductor body 10. The wavelength of the laser pulse is below 400 nm and is thus essentially absorbed by the coating 20 without penetrating any further into the semiconductor body 10 and the active region 24 arranged within the semiconductor body 10. The absorption of the laser energy in the coating 20 heats it up considerably and transfers its energy back to the adhesive layer 31, for example. As a result, the adhesive layer 31 changes in its structure and adhesive behavior, so that the adhesive force between the interface of the coating 20 and the adhesive layer 31 is greatly reduced and the component 1 detaches.

Alternatively, it is also conceivable that the coating 20 in the area of the emission surface 27, i.e. in this embodiment in the complete area of the second main side, is dissolved by the irradiated laser energy or its structure is changed in such a way that the adhesive force is also greatly reduced here and thus the component 1 detaches from the glass substrate 30. If organic material were used as coating 20, it would thus be possible, for example, for the coating 20 to be vaporized by the irradiated laser energy, so that no further material of the coating 20 remains on the second main side of the semiconductor body 10 and in particular in the area of the light-emitting surface 27.

In the embodiment shown in FIG. 2, the adhesive layer 31 is bonded to the entire second main side of the semiconductor components 1. In contrast, FIG. 3 shows a further embodiment in which the adhesive layer 32 is structured so that it forms distinct and separate areas on the glass substrate 30. A semiconductor body 10 is now attached to each of these individual areas with its second main side. The area of each region of the adhesive layer 32 is smaller than the area of the second main side of each semiconductor device attached thereto. In some embodiments, the area of the adhesive layer may also be smaller than the associated light emitting area. This makes it possible to focus the irradiated laser energy on a significantly smaller point and thus to have to irradiate less energy overall. Any thermal load that may occur due to energy transport of the light absorbed by the coating 20 is thus further reduced.

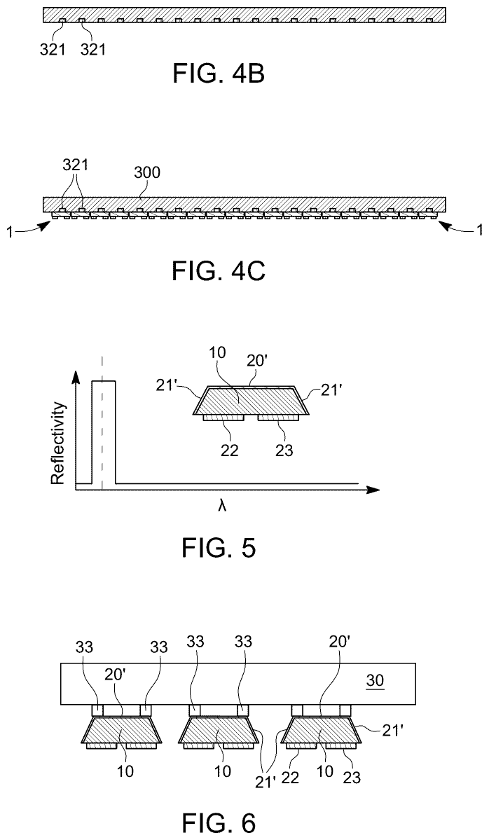

FIGS. 4A to 4C show a schematic embodiment of a manufacturing process for transferring semiconductor devices according to the proposed principle. In this, a glass carrier substrate 300 is provided in sub-figure A), which comprises a plurality of recesses 301 in a surface. The depressions 301 are, for example, square or round or rectangular or polygonal and are produced in the substrate carrier 30 by suitable photolithographic measures. In some embodiments, the glass carrier substrate 30 is designed as a transparent glass carrier.

In partial FIG. 4B, an adhesive layer is now applied to the glass substrate 300. The material of this adhesive layer not only covers the surface of the glass substrate 300, but also extends into the recesses 301 in a subsequent step not shown here, the material of the adhesive layer is removed again from the surface of the carrier substrate 300, remains only in the previously produced recesses 301 and closes there essentially flush. In a subsequent step, a plurality of semiconductor components are now attached to the adhesive layer 321 in the recesses 301 with their respective second main side by means of a transfer process. As shown in the illustrated embodiment example, the area of the adhesive layer 321 in the recesses 301 is smaller than the area of the second main side. In other words, the second main side extends beyond the recesses and lies flush against the surface of the glass support substrate.

FIG. 5 shows a further embodiment of a semiconductor device according to the proposed principle. In these, the semiconductor component comprises a reflective coating 20′ on the second main side and thus the emission surface. The component 1 is designed in a similar way to the previous embodiments. As in the diagram also shown in FIG. 5, the reflective coating 20 comprises a high transparency in the visible spectrum and at the same time comprises a high reflectivity at the second main wavelength below 390 nm. The reflectivity is 80% to 90%. When the semiconductor components are transferred from a glass substrate to a carrier or a PCB, a detachment light pulse is reflected by the coating 20′ and thus does not reach the semiconductor body 10. In this way, thermal stress or penetration of the laser light into the active zone of the semiconductor body 10 is avoided.

In this respect, FIG. 6 shows an embodiment with which such a transfer process can be carried out. The semiconductor components are connected with their semiconductor bodies on the second main side to a glass substrate 30 via an adhesive layer 33. The adhesive layer is designed to absorb the light of the second main wavelength. Furthermore, as shown, the adhesive layer 33 is not applied over the entire surface of the second main side, but only in the edge area next to the side flank. The adhesive layer 33 can be designed in the form of a ring or a surrounding rectangle (see also FIG. 10) or square, for example. For detachment, a laser pulse with the second main wavelength is irradiated through the glass substrate 30 onto the surface of the second main side of the semiconductor body 10. The coating 20′ on the second main side causes the irradiated laser light to be reflected in the direction of the material of the adhesion layer 31, among other things. Laser light irradiated directly onto the material of the adhesion layer 33 and the reflected laser light are absorbed by the adhesion layer 33 and cause it to heat up. Due to the heating, the consistency of the adhesive layer changes and the adhesive force is reduced so that the component is detached.

In some embodiments, the semiconductor device can be provided with a roughened surface in order to achieve better light extraction in this way. Such a roughened surface can also be covered with a coating. In the case of an absorbent thin coating, the roughening used is of secondary importance, as the absorption heats the coating and thus reduces the adhesive force. The situation is different with a reflective coating. Depending on the reflective material, it is advisable to provide a periodic structure on the second main side instead of a random roughening. Such a structure allows the light generated by the semiconductor body to be decoupled well via the emission on the one hand and to achieve sufficient reflectivity for light of the second main wavelength in the coating on the other.

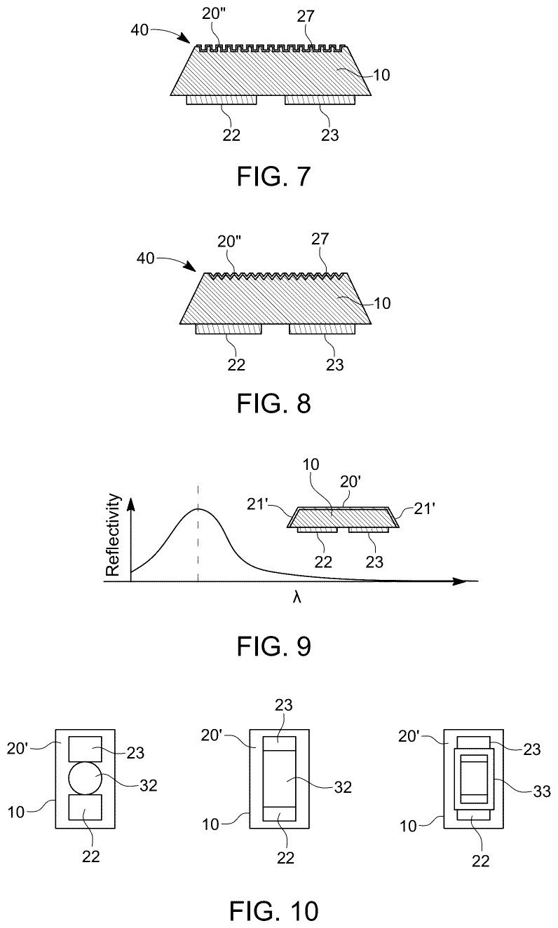

FIGS. 7 and 8 show two such embodiments. In FIG. 7, a periodic strip-shaped structure 40 is arranged on the second main side and the emission surface 27. This is designed in the form of trenches, the surface of each of which is covered with a coating 20″. Irradiated light of the second main wavelength is reflected by the periodic structure of the coating. The periodicity, i.e. the size and design of the trenches, can be matched both to the decoupling and to the reflection properties of the coating 20″. A further embodiment example is shown in FIG. 8, in which the second main side is structured with pyramid-shaped elevations. The surface of the pyramid-shaped structures is also provided with the reflective coating 20″.

FIG. 9 shows another embodiment example in which the coating is designed as a reflective coating. This is a thin layer of silicon nitride SiN, which was deposited on the surface and the second main side of the semiconductor body during the manufacturing process after mesa structuring the individual semiconductor components. The silicon nitride layer 20′ is only a few atoms thick. Its thickness is selected in such a way that light of the second main wavelength, i.e. in the range of 400 nm, is reflected and emitted upwards again. However, the silicon nitride layer 20′ is essentially transparent in the region of the emission wavelength of the semiconductor body.

In addition to the proposed coating, a further layer between the glass substrate and the semiconductor body is also required for the transfer process. This layer, generally referred to as an adhesion layer, can be transparent or absorbent for the light of the second main wavelength, depending on the design. It is possible to adjust the energy required for detachment by structuring the adhesive layer appropriately and, in particular, to reduce it to such an extent that any thermal load on the component is minimized.

FIG. 10 shows different embodiments of such an adhesive layer in its partial figures in a top view of the adhesive layer through the respective substrate. The semiconductor bodies 10 show the two contact pads 22 and 23 on their underside, which are shown again in the illustration for the sake of clarity. In the left-hand embodiment example of FIG. 10, the adhesive layer 32 is formed by a round element arranged in the center. In this embodiment, it is conceivable to make the adhesive layer both transparent and absorbent.

In the case of a transparent adhesive layer 32, the coating of the semiconductor body is absorbent. When laser light of the second main wavelength is irradiated precisely in the area of the adhesive layer 32, the underlying coating is heated and the adhesive force between the adhesive layer 32 and the coating of the semiconductor body is reduced. In the case of an absorbing adhesive layer 32, the light of the second main wavelength is absorbed by the adhesive layer 32 on the one hand and reflected by the coating arranged underneath or next to it. Part of the source of the reflected light in turn reaches the adhesive layer, where it can lead to further heating of the adhesive layer 32. In the middle partial figure, the adhesive layer 32 is formed by a rectangular element that extends along the semiconductor body above the two contact elements 22 and 23. As in the embodiment of the left-hand partial figure, a transparent or an absorbent adhesive layer is also conceivable in this embodiment.

The right-hand partial figure in FIG. 10 shows an adhesive layer 33, which is designed as a circumferential edge. The thickness of the edge is selected such that the absorbing adhesive layer just supports the semiconductor body. In this way, an irradiated laser light of the second main wavelength is either absorbed by the adhesive layer 33 or reflected back again by the underlying coating. The energy irradiated and absorbed in this way is sufficient to change the structure and adhesive force of the adhesive layer 33 so that the component detaches. Due to the very thin adhesive layer 33 on the coating, the thermal load on the component during the detachment process is reduced to a minimum.

1.-15. (canceled)

16. A semiconductor device comprising:
a semiconductor body configured to generate light of a first main wavelength, wherein the semiconductor body comprises a first main side having at least one contact region and a second main side opposite the first main side having a light-emitting surface; and
a coating arranged on the second main side, wherein the coating is substantially transparent to light in a wavelength range of the first main wavelength and is absorbent or reflective to light in a wavelength range of a second main wavelength,
wherein the wavelength range of the second main wavelength is below the wavelength range of the first main wavelength and below 450 nm, and
wherein the coating comprises a multilayer coating sequence of materials of different refractive indices.

17. The semiconductor device according to claim 16, wherein a degree of absorption or a degree of reflection of the coating in the wavelength range of the second main wavelength is more than 80%.

18. The semiconductor device according to claim 16, wherein a thickness of the coating is between 50 nm and 500 nm, inclusive.

19. The semiconductor device according to claim 16, wherein the coating comprises a dielectric mirror comprising a plurality of layers of different refractive indices.

20. The semiconductor device according to claim 16, wherein the coating comprises SiN, or wherein the coating comprises a multilayer structure comprising at least one of the following materials:
SiO2,
SiNx,
TiO2,
Nb2O5,
ITO,
Al2O3,
AlF3, or
MgF2.

21. The semiconductor device according to claim 16, wherein the coating on the light-emitting surface is at least partially removed.

22. The semiconductor device according to claim 16, wherein the light-emitting surface comprise a regular surface structure, and wherein the coating extends along a roughening.

23. The semiconductor device according to claim 16, further comprising side faces extending from the second main side at an angle of less than 90° towards the first main side, and wherein the coating extends at least partially onto the side faces.

24. The semiconductor device according to claim 16, wherein the coating comprises an organic material.

25. A method for transferring a semiconductor device, wherein the semiconductor device comprises a semiconductor body for generating light of a first main wavelength, and wherein the semiconductor body comprises a first main side having at least two contact regions and a second main side opposite the first main side having a light-emitting surface, wherein the semiconductor device comprises a coating arranged on the second main side, which is substantially transparent to light in a wavelength range of the first main wavelength and is absorbent or reflective to light in a wavelength range of a second main wavelength, and wherein the wavelength range of the second main wavelength is smaller than the wavelength range of the first main wavelength and is below 450 nm, the method comprising:
providing a carrier substrate with a substantially transparent adhesive layer arranged thereon;
arranging a plurality of semiconductor devices with the second main side on the adhesive layer;
irradiating with a pulse of the second main wavelength; and
absorbing the irradiated pulse by the coating so that an adhesive force between the coating and the adhesive layer is reduced such that the semiconductor device detaches.

26. The method according to claim 25, wherein the adhesive layer is structured and covers only a part of the second main side.

27. The method according to claim 25, wherein the carrier substrate is substantially transparent to light of the second main wavelength.

28. The method according to claim 25, wherein providing the carrier substrate comprises:
providing a structured carrier substrate having a plurality of depressions; and
filling the plurality of depressions with a material from the adhesive layer.

29. The method according to claim 25, wherein providing the carrier substrate comprises:
providing the carrier substrate;
applying an unstructured adhesive layer; and
patterning the adhesive layer such that the adhesive layer comprises a plurality of separated regions, each separated region comprising an area that is less than or substantially equal to an area of the second main side.

30. A method for transferring a semiconductor device, wherein the semiconductor device comprises a semiconductor body for generating light of a first main wavelength, wherein the semiconductor body has a first main side having at least two contact regions and a second main side having a light-emitting surface on the first main side, wherein the semiconductor device comprises a coating being arranged on the second main side, which is substantially transparent for light in a wavelength range of the first main wavelength and is absorbent or reflective for light in a wavelength range of a second main wavelength, and wherein the wavelength range of the second main wavelength is smaller than the wavelength range of the first main wavelength and is below 450 nm, the method comprising:
providing a carrier substrate with an adhesive layer arranged thereon, which absorbs the second main wavelength;
arranging a plurality of semiconductor devices with the second main side on the adhesive layer;
irradiating with a pulse of the second main wavelength; and
reflecting at least part of the irradiated pulse through the coating back onto the adhesive layer so that the latter is heated and am adhesive force between the coating and the adhesive layer is reduced by the heating such that the semiconductor component detaches.

31. The method according to claim 30, wherein the adhesive layer is structured and covers only a part of the second main side.

32. The method according to claim 30, wherein the carrier substrate is substantially transparent to light of the second main wavelength.

33. The method according to claim 30, wherein providing the carrier substrate comprises:
providing a structured carrier substrate having a plurality of depressions; and
filling the plurality of depressions with a material from the adhesive layer.

34. The method according to claim 30, wherein providing the carrier substrate comprises:
providing the carrier substrate;
applying an unstructured adhesive layer; and
patterning the adhesive layer such that the adhesive layer comprises a plurality of separated regions, each separated region comprising an area that is less than or substantially equal to an area of the second main side.
